(19) United States
(12) Patent Application Publication
(10) Pub. No.: US 2026/0219591 A1
(43) Pub. Date: Jul. 30, 2026

(54) SYSTEM AND METHOD FOR DISCHARGING A PATTERNING DEVICE

(71) Applicant: ASML NETHERLANDS B.V., Veldhoven (NL)

(72) Inventors: Vladimir KVON, Eindhoven (NL); Lucas Christiaan Johan HEIJMANS, Eindhoven (NL); Andrey NIKIPELOV, Eindhoven (NL); Zahra MARVI, Eindhoven (NL); Max KOOLE, Eindhoven (NL)

(73) Assignee: ASML NETHERLANDS B.V., Veldhoven (NL)

(21) Appl. No.: 19/144,953

(22) PCT Filed: Dec. 8, 2023
(86) PCT No.: PCT/EP2023/084902

§ 371 Date: Jun. 30, 2025

(30) Foreign Application Priority Data
Jan. 13, 2023 (EP) 23151475.3

(51) Int. Cl. G03F 7/00; G03F 1/82

(52) U.S. Cl. CPC G03F 7/70941; G03F 1/82

(57) ABSTRACT

A light source arranged to illuminate a non-patterning surface of a patterning device in a lithographic apparatus, wherein the light source is configured such that, in response to illumination from the light source, the non-patterning surface emits electrons due to the photoelectric effect. Advantageously, when the non-patterning surface is charged, the non-patterning surface may be discharged before it is unloaded.

### CROSS-REFERENCE TO RELATED APPLICATIONS

This application claims priority of EP Application Serial No. 23151475.3 which was filed on 13 Jan. 2023, and which is incorporated herein in its entirety by reference.

### FIELD

The present invention relates to the discharging of a charged surface of a patterning device in a lithographic apparatus. Embodiments provide a system and method that use the photoelectric effect to discharge a charged surface of a patterning device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k1 is a process-dependent adjustment factor, also called the Rayleigh constant, and CD is the feature size (or critical dimension) of the printed feature. It follows from Equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

Once the EUV radiation has been generated, it is directed through the lithographic apparatus by a plurality of mirrors to a patterning surface of the patterning device, which imparts the desired pattern to the EUV radiation.

The performance and reliability of the pattering device is critical to the effectiveness and efficiency of the lithographic process. Any damage to the patterning device, or related features to the patterning device, may increase the downtime of the lithographic apparatus and significantly reduce the yield of the manufacturing process. There is a general need to improve the performance and reliability of the pattering device of a lithographic apparatus.

### SUMMARY OF THE INVENTION

According to a first aspect of the present invention, there is provided a light source arranged to illuminate a non-patterning surface of a patterning device in a lithographic apparatus, wherein the light source is configured such that, in response to illumination from the light source, the non-patterning surface emits electrons due to the photoelectric effect.

According to a second aspect of the present invention, there is provided a patterning device discharge system for use in a lithographic apparatus, the system comprising: a patterning device; a support structure for holding the patterning device in the lithographic apparatus; and one or more light sources according to the first aspect.

According to a third aspect of the present invention, there is provided a lithographic apparatus comprising: a system according to the second aspect; and a controller arranged to control the illumination of the patterning device of the system by the one or more light sources of the system.

According to a fourth aspect of the present invention, there is provided a method of reducing the charge of a charged non-patterning surface of a patterning device in a lithographic apparatus, the method comprising illuminating the non-patterning surface with light such that the non-patterning surface emits electrons due to the photoelectric effect.

According to a fifth aspect of the present invention, there is provided a method for use in the manufacturing a device, the method comprising the method of the fourth aspect.

### BRIEF DESCRIPTION OF THE DRAWINGS

Embodiments of the invention will now be described, by way of example only, with reference to the accompanying schematic drawings, in which corresponding reference symbols indicate corresponding parts.

FIG. 1 schematically depicts a lithographic apparatus.

FIG. 2 schematically depicts a more detailed view of the lithographic apparatus.

FIG. 3 schematically depicts a patterning device that is secured to a support structure.

FIG. 4 schematically depicts a patterning device discharge system according to an embodiment.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

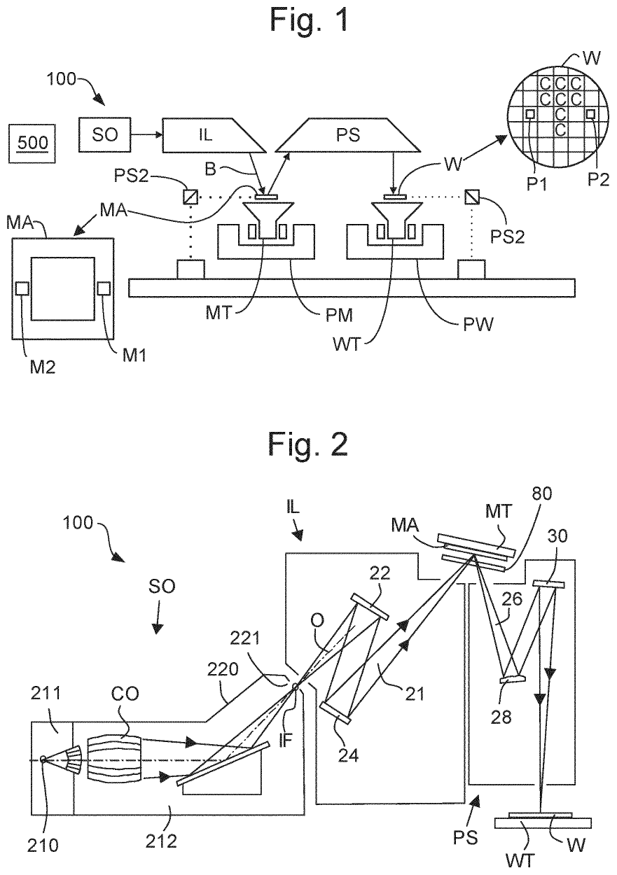

FIG. 1 schematically depicts a lithographic apparatus 100 including a source collector module SO according to one embodiment of the invention. The apparatus 100 comprises:
an illumination system (or illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern-imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” should be broadly interpreted as referring to any device that can be used to impart a radiation beam B with a pattern in its cross-section such as to create a pattern in a target portion C of the substrate W. The pattern imparted to the radiation beam B may correspond to a particular functional layer in a device being created in the target portion C, such as an integrated circuit.

Examples of patterning devices include masks, programmable mirror arrays, and programmable liquid-crystal display (LCD) panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the lithographic apparatus 100 is of a reflective type (e.g., employing a reflective mask).

The lithographic apparatus 100 may be of a type having two (dual stage) or more substrate tables WT (and/or two or more support structures MT). In such a “multiple stage” lithographic apparatus the additional substrate tables WT (and/or the additional support structures MT) may be used in parallel, or preparatory steps may be carried out on one or more substrate tables WT (and/or one or more support structures MT) while one or more other substrate tables WT (and/or one or more other support structures MT) are being used for exposure.

Referring to FIG. 1, the illumination system IL receives an extreme ultraviolet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module SO may be separate entities, for example when a CO₂ laser is used to provide the laser beam for fuel excitation.

In such cases, the laser is not considered to form part of the lithographic apparatus 100 and the radiation beam B is passed from the laser to the source collector module SO with the aid of a beam delivery system comprising, for example, suitable directing mirrors and/or a beam expander. In other cases the source may be an integral part of the source collector module SO, for example when the source is a discharge produced plasma EUV generator, often termed as a DPP source.

The illumination system IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illumination system IL can be adjusted. In addition, the illumination system IL may comprise various other components, such as facetted field and pupil mirror devices. The illumination system IL may be used to condition the radiation beam B, to have a desired uniformity and intensity distribution in its cross-section.

The radiation beam B is incident on the patterning device (e.g., mask) MA, which is held on the support structure (e.g., mask table) MT, and is patterned by the patterning device MA. After being reflected from the patterning device (e.g., mask) MA, the radiation beam B passes through the projection system PS, which focuses the radiation beam B onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. The patterning device (e.g., mask) MA and the substrate W may be aligned using mask alignment marks M1, M2 and substrate alignment marks P1, P2.

A controller 500 controls the overall operations of the lithographic apparatus 100 and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus 100. It will be appreciated that a one-to-one relationship between controlling computer and lithographic apparatus 100 is not necessary. In an embodiment of the invention one computer can control multiple lithographic apparatuses 100. In an embodiment of the invention, multiple networked computers can be used to control one lithographic apparatus 100. The controller 500 may also be configured to control one or more associated process devices and substrate handling devices in a lithocell or cluster of which the lithographic apparatus 100 forms a part. The controller 500 can also be configured to be subordinate to a supervisory control system of a lithocell or cluster and/or an overall control system of a fab.

FIG. 2 shows the lithographic apparatus 100 in more detail, including the source collector module SO, the illumination system IL, and the projection system PS. An EUV radiation emitting plasma 210 may be formed by a plasma source. EUV radiation may be produced by a gas or vapor, for example Xe gas, Li vapor or Sn vapor in which the radiation emitting plasma 210 is created to emit radiation in the EUV range of the electromagnetic spectrum. In an embodiment, a plasma of excited tin (Sn) is provided to produce EUV radiation.

The radiation emitted by the radiation emitting plasma 210 is passed from a source chamber 211 into a collector chamber 212.

The collector chamber 212 may include a radiation collector CO. Radiation that traverses the radiation collector CO can be focused in a virtual source point IF. The virtual source point IF is commonly referred to as the intermediate focus, and the source collector module SO is arranged such that the virtual source point IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the unpatterned beam 21, at the patterning device MA, as well as a desired uniformity of radiation intensity at the patterning device MA. Upon reflection of the unpatterned beam 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in the illumination system IL and the projection system PS. Further, there may be more mirrors present than those shown in the Figures, for example there may be 1-6 additional reflective elements present in the projection system PS than shown in FIG. 2.

Alternatively, the source collector module SO may be part of an LPP radiation system.

As depicted in FIG. 1, in an embodiment the lithographic apparatus 100 comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The space intervening between the projection system PS and the substrate table WT can be at least partially evacuated. The intervening space may be delimited at the location of the projection system PS by a solid surface from which the employed radiation is directed toward the substrate table WT.

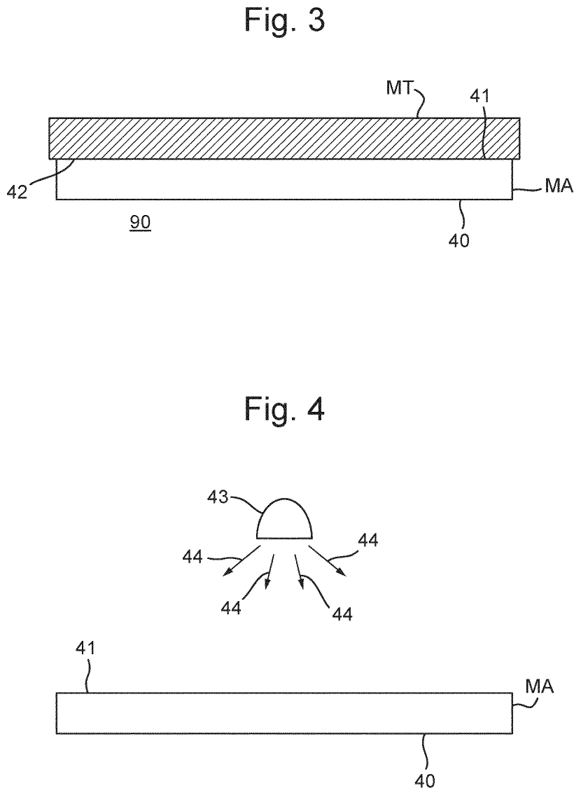

FIG. 3 depicts a schematic representation of a patterning device MA clamped to a support structure MT. As described above, the support structure MT may use mechanical, vacuum, electrostatic or other clamping techniques to hold the patterning device MA. The support structure MT may comprise a plurality of burls (cone-shaped protrusions) on a supporting surface 42 of the support structure MT that faces a non-patterning surface 41 of the patterning device MA. When the patterning device MA is clamped to the support structure MT, the non-patterning surface 41 faces the support structure MT and is in contact with distal ends of the plurality of burls. It is not necessary for each of the plurality of burls to be in contact with the non-patterning surface 41. These burls are not shown in FIG. 3. The non-patterning surface 41 may be referred to as the backside of the patterning device MA. The patterning surface 40 may be referred to as the front-side of the patterning device MA.

Both the patterning device MA and support structure MT may be contained within a patterning device environment 90. The patterning device environment 90 may be separated from an external environment surrounding the lithographic apparatus 100 and/or other components within the lithographic apparatus such that gases and contaminant particles P are substantially prevented from entering the patterning device environment 90.

The patterning device environment 90 may be partially evacuated of gas. That is, the pressure within the patterning device environment 90 may be less than ambient pressure. This is to limit the attenuation of EUV radiation as it travels through the patterning device environment 90.

As shown in FIG. 2, but not shown in FIG. 3, a pellicle 80 may at least partially cover the patterning device MA. The purpose of the pellicle 80 is to substantially prevent any contaminant particles in the patterning device MA environment 90 from reaching a surface of the patterning surface 40.

A problem that may occur in EUV systems is that a patterning device MA may become electrically charged by EUV-induced plasma that is generated near the patterning device MA by the EUV radiation. In particular, charge may accumulate on the non-patterning surface 41 of the patterning device MA. When the charged patterning device MA is unloaded from its support structure MT, a substantial potential difference may be generated between the patterning device MA and the support structure MT due to the loss of capacitive coupling to the support structure MT. The generated potential difference may cause damage to the patterning device MA and/or the pellicle 80 for the patterning device MA.

A known technique for solving the problem caused by the charging of the patterning device MA is to generate a plasma around the patterning device MA by illuminating the patterning device MA with EUV light. When the patterning device MA is removed from its support structure MT, the plasma may reach the non-patterning surface 41 of the patterning device MA. Electrical conduction through the plasma may discharge the patterning device MA and thereby reduce the likelihood of damage occurring due to the charging of the patterning device MA.

There are a number of problems with the above-described known technique. The additional use of EUV light for discharging the patterning device MA substantially increases the energy requirement and also reduces the lifetime of the EUV source. Most of the charge accumulation may occur on the non-patterning surface 41 and the EUV plasma is not able to discharge this surface until the patterning device MA has been moved from its support structure MT. A potential difference build-up still occurs when the patterning device MA is removed from its support structure MT, although the EUV plasma may reduce the magnitude and/or duration of the potential difference.

Embodiments provide a new technique for discharging a charged surface of a patterning device MA that reduces, or avoids, one or more of the above problems.

Embodiments provide a light source within the lithographic apparatus for illuminating at least part of the patterning device MA. The illumination from the light source is arranged so that is causes the patterning device MA to emit electrons due to the photoelectric effect. This may substantially discharge the patterning device MA and thereby prevent, or reduce, the problem of voltage build-up when the patterning device MA is unloaded from its support structure MT.

FIG. 4 schematically shows an arrangement of a patterning device discharge system according to an embodiment. A light source 43 is arranged to illuminate the patterning device MA with photons 44.

The illuminated surface of the patterning device MA may be a surface of the patterning device MA on which substantial charge accumulation has occurred. In particular, the illuminated surface may be the non-patterning surface 41 of the patterning device MA.

The material of the illuminated surface is a known property of the patterning device MA. The illuminated surface may be made of the same material as the main body of the patterning device MA. Alternatively, the patterning device MA may be at least partially coated so that the illuminated surface comprises a different material from the main body of the patterning device MA.

The light source 43 is configured so that the emitted photons 44 are suitable for causing the photoelectric effect to occur in the illuminated surface. The power and wavelength of the emitted light from the light source 43 may therefore be determined in dependence on the requirements for causing the photoelectric effect in the specific material of the illuminated surface.

The light source 43 may also be configured so that the emitted light does not result in plasma generation near the patterning device MA. There may be hydrogen gas present near the patterning device MA and the light source 43 may be configured so that substantial ionization of the hydrogen gas does not occur. Advantageously, this avoids the risk of hydrogen ionization causing an electrical breakdown and/or plasma related effects occurring.

Hydrogen ionization typically occurs in the 13.6 eV energy spectrum, which corresponds to a light with a wavelength of 91 nm. Hydrogen ionization may therefore be substantially avoided by the light source 43 emitting photons 44 with energies below 13.6 eV, i.e. photon 44 wavelengths that are longer than 91 nm. The maximum energy of the photons 44 emitted by the light source 43 may therefore be 11 eV or less, which corresponds to photons 44 with wavelengths of 113 nm or longer.

The required power of the light source 43 may be determined in dependence on the required charge reduction of the illuminated surface in order for the illuminated surface to be substantially discharged. This may be determined in dependence on a determination, or estimation, of how much charge needs to be extracted, the voltage at the illuminated surface, and the photo-yield of the illuminated surface. The photo-yield is the number of electrons that are emitted from the illuminated surface in response to a number of incident photons 44. A photo-yield of 1 indicates that one electron is emitted for each single incident photon 44. The photo-yield is dependent on the type of illuminated material and the energies of the incident photons 44.

If the desired current for discharging the illuminated surface is, for example, 50 nA, and the voltage of the illuminated surface is, for example, 150V, the required power of the photons 44 that result in electron generation would be 7.5 μW. The material of the illuminated surface may be, for example, Chromium. When illuminated with electrons that have an energy of 11 eV, which corresponds to a wavelength of 113 nm, the photo-yield of Chromium is about 0.01. The required power of the light source 43, that emits photons 44 with a wavelength of 113 nm, would therefore need to be about 0.75 mW. A lower light source power may be used if a longer discharge time is acceptable. The light source power may therefore, for example, be in the range of about 0.07 mW to 0.75 mW.

The illuminated surface may be made from a number of different materials and is not restricted to being pure Chromium. When a different material for the illuminated surface is used, the same photon energies may still be used, and these may be 11 eV or less so as to avoid any Hydrogen ionization. However, a different light source power may be used due to the different photo-yield of the illuminated surface. For example, the illuminated surface may comprise Nickel and/or Tantalum. For these materials the photo-yield increases to about 0.08. The required light source power may therefore be reduced to a power in the range of about 8 μW to 94 μW.

The required light source power may depend on one or more of the material of the surface being illuminated, the charge of the surface being illuminated and the desired discharge rate of the surface being illuminated. The required light source power may be, for example, in the range of about 5 μW to 1 mW.

The power of the emitted light from the light source 43 may be tunable. An appropriate power of the emitted light may be determined in dependence on the material of the surface of the patterning device MA that the light source 43 is arranged to illuminate. The light source 43 may then be configured so that it emits light with the determined power.

The wavelength of the emitted light from the light source 43 may be tunable. An appropriate wavelength of the emitted light may be determined in dependence on the material of the surface of the patterning device MA that the light source 43 is arranged to illuminate. The light source 43 may then be configured so that it emits light with the determined wavelength.

The illuminated surface may be an alloy that comprises two or more of Chromium, Nickel, Tantalum and/or other materials. The required light source power may be determined in dependence on the photo-yield of the illuminated surface.

The light source 43 may be any of a number of different commercially available light sources. The light source 43 may be a laser, or another type of light source 43. The light source 43 may be, for example, a Krypton or Xenon based lamp that is suitable for use in a vacuum. The light source 43 may be, for example, one of the ultraviolet (UV) light sources shown at https://resonance.on.ca/high-power-vuv-light-source/(as viewed on 5 Jan. 2023). The light sources 43 may emit light with an appropriate wavelength as required for the techniques of embodiments. The light sources 43 may also emit light with an appropriate power as required for the techniques of embodiments.

Embodiments provide a patterning device discharge system that is located within a lithographic apparatus. The patterning device discharge system comprises a patterning device arrangement and one or more light sources 43. The patterning device arrangement may comprise a patterning device MA and a support structure MT of the patterning device MA. The patterning device MA may be arranged and operated according to known techniques. Each light source 43 may be one of the above-described light sources 43. Each light source 43 may be arranged so that it may illuminate at least one surface of the patterning device MA. Each light source 43 may be configured so that, in response to the illumination of a surface of the patterning device MA by the light source 43, the illuminated surface emits electrons due to the occurrence of the photoelectric effect.

Embodiments include a number of different implementations of each light source 43 of the patterning device discharge system.

In a first implementation of the patterning device discharge system, the light source 43 may be integrated into, or located behind, the support structure MT of the patterning device MA. The support structure MT may comprise apertures. The light source 43 may be arranged so that it emits light through the apertures and onto the non-patterning surface 41 of the patterning device MA. Advantageously, the patterning device MA may be illuminated by the light source 43 before the patterning device MA is removed from its support structure MT. The patterning device MA may therefore be substantially discharged prior to being removed from its support structure MT. This may substantially prevent any potential difference build-up between the patterning device MA and its support structure MT from occurring when the patterning device MA is removed from its support structure MT.

Embodiments include a method of operation with the first implementation of the patterning device discharge system. A patterning device MA may be illuminated in an EUV lithographic process. Charge may build-up on the non-patterning surface 41 of the patterning device MA during the illumination process. After the illumination process has been completed, the light source 43 may start emitting light that illuminates the non-patterning surface 41 of the patterning device MA. Due to the photo-electric effect, the electrons may be emitted from the non-patterning surface 41 and the non-patterning surface 41 thereby substantially discharged. The light source 43 may then stop emitting light so that the photo-electric effect no longer occurs. The patterning device MA may then be removed from its support structure MT.

In a second implementation of the patterning device discharge system, the light source 43 may be a separate structure from the support structure MT of the patterning device MA. The light source 43 may be located away from the support structure MT, such as to the side of the support structure MT. The light source 43 may be located, for example, on an arm of a handler that is used to exchange patterning devices MA. The patterning device MA may be removed from its support structure MT and positioned so that the light source 43 may illuminate the non-patterning surface 41 of the patterning device MA. The second implementation may require the patterning device MA to be removed from its support structure MT when the patterning device MA is charged. This may result in an initial potential difference build-up between the patterning device MA and its support structure MT. However, an advantage of the second implementation is that it may not require any modification to the existing designs of support structures MT for patterning devices MA.

Embodiments include a method of operation with the second implementation of the patterning device discharge system. A patterning device MA may be illuminated in an EUV lithographic process. Charge may build-up on the non-patterning surface 41 of the patterning device MA during the illumination process. After the illumination process has been completed, the patterning device MA may be removed from its support structure MT and positioned so that its non-patterning surface 41 may be illuminated by the light source 43. The light source 43 may start emitting light that illuminates the non-patterning surface 41 of the patterning device MA. Due to the photo-electric effect, the electrons may be emitted from the non-patterning surface 41 and the non-patterning surface 41 thereby substantially discharged. The light source 43 may then stop emitting light so that the photo-electric effect no longer occurs. The charge reduction due to the photo-electric effect may reduce the magnitude and/or duration of any potential difference build-up that occurs between the patterning device MA and its support structure MT.

Embodiments provide a number of advantages over known techniques. In particular, charge build-up on a surface of the patterning device MA may be neutralized without requiring the use of the EUV source. This increases the lifetime of the EUV source. In embodiments, the required power for discharging the patterning device MA may be a lot lower than when an EUV source is used. Embodiments may therefore provide an overall energy saving. Embodiments may also result in the patterning device MA being heating less than when the known technique for discharging the patterning device MA is performed. In embodiments, each light source 43 may be operated independently of the EUV source and this may allow faster exchanges of patterning devices MA. In the first implementation of the patterning device discharge system, the patterning device MA may be discharged prior to being unloaded from its support structure MT and this may prevent any initial potential difference build-up.

Embodiments include a number of modifications and variations to the above described techniques.

Although the techniques of embodiments have been described as being applied in an EUV lithographic system, the techniques of embodiments may be applied in any type of lithographic system. For example, the techniques of embodiments may be applied in a DUV lithographic system.

Embodiments include the patterning device discharge system comprising more than one light source 43 for illuminating the pattering device MA. For example, a first light source 43 may be integrated into, or located behind, the support structure MT of the patterning device MA as described above for the first implementation of the patterning device discharge system. A second light source 43 may be located away from the support structure MT, such as to the side of the support structure MT as described above for the second implementation of the patterning device discharge system. The first and/or second light source 43 may be used to discharge the patterning device MA.

In embodiments, the light source 43 is not restricted to illuminating the non-patterning surface 41 of the patterning device MA. Embodiments include the light source 43 being arranged to illuminate any surface of the patterning device MA. For example, the light source 43 and a handler of the patterning device MA may be configured so that all surfaces of the patterning device MA on which substantial charge build-up may occur may be illuminated.

In the above described first implementation of the patterning device discharge system, the light source 43 may be used to discharge the patterning device MA prior to each process of unloading a patterning device MA from its support structure MT. The process of discharging the patterning device MA may be performed once, after all of the lithographic processes with the patterning device MA have been completed. Alternatively, the process of discharging the patterning device MA may be performed more than once whilst a patterning device MA is loaded on its support structure MT. This may reduce the maximum amount of charge build-up that occurs during the use of the patterning device MA. The light source 43 may discharge the patterning device MA between lithographic processes performed with the patterning device MA. Embodiments also include the light source 43 discharging the patterning device MA whilst a lithographic process is performed with the pattering device.

The light source(s) 43 for discharging a patterning device may be incorporated into a lithographic apparatus. The lithographic apparatus may be used for the manufacture of ICs.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

Aspects of the invention are described in the following numbered clauses:
1. A light source arranged to illuminate a non-patterning surface of a patterning device in a lithographic apparatus, wherein the light source is configured such that, in response to illumination from the light source, the non-patterning surface emits electrons due to the photoelectric effect.
2. The light source according to clause 1, wherein the light source is arrange to emit light with a wavelength that is greater than 91 nm, preferably and at least 113 nm.
3. The light source according to clause 1 or 2, wherein the power of the light emitted the light source is less than 1 mW.
4. The light source according to any preceding clause, wherein the power of the light emitted by the light source is greater than 5 μW.
5. The light source according to any preceding clause, wherein the light source is tuneable so that the wavelength and or power of the emitted light may be changed.
6. The light source according to any preceding clause, wherein the non-patterning surface of the patterning device is on the opposite side of the patterning device to a patterning surface of the patterning device.
7. The light source according to any preceding clause, wherein the lithographic apparatus is an EUV lithographic apparatus or a DUV lithographic apparatus.
8. A patterning device discharge system for use in a lithographic apparatus, the system comprising:
a patterning device;
a support structure for holding the patterning device in the lithographic apparatus; and
one or more light sources according to any preceding clause.
9. The system according to clause 8, wherein the support structure is arranged such that a non-patterning surface of the patterning device faces the support structure when the patterning device is held by the support structure; and
at least one light source is arranged to illuminate the non-patterning surface of the patterning device when the patterning device is held by the support structure.
10. The system according to clause 9, wherein the support structure comprises one or more openings; and
the at least one light source that is arranged to illuminate the non-patterning surface of the patterning device, when the patterning device is held by the support structure, is arranged to shine light through the one or more openings.
11. The system according to clause 9 or 10, wherein the at least one light source that is arranged to illuminate the non-patterning surface of the patterning device, when the patterning device is held by the support structure, is arranged in the support structure.
12. The system according to any of clauses 8 to 11, further comprising a handler of the patterning device;
wherein the handler is arranged to move the patterning device away from the support structure to an illumination location; and
at least one light source is arranged to illuminate the patterning device when the patterning device is at the illumination location.
13. The system according to any of clauses 8 to 12, wherein the lithographic apparatus is an EUV lithographic apparatus or a DUV lithographic apparatus.
14. A lithographic apparatus comprising:
a system according to any of clauses 8 to 13; and
a controller arranged to control the illumination of the patterning device of the system by the one or more light sources of the system.
15. The lithographic apparatus according to clause 14, wherein, when the patterning device of the system is charged, the controller is arranged to control the illumination of the patterning device by the one or more light sources of the system so that the patterning device is substantially discharged.
16. The lithographic apparatus according to clause 14 or 15, wherein the lithographic apparatus is an EUV lithographic apparatus or a DUV lithographic apparatus.
17. A method of reducing the charge of a charged non-patterning surface of a patterning device in a lithographic apparatus, the method comprising illuminating the non-patterning surface with light such that the non-patterning surface emits electrons due to the photoelectric effect.
18. The method according to clause 17, wherein the lithographic apparatus is according to any of clauses 14 to 16.
19. A method for use in the manufacturing a device, the method comprising the method of clause 17 or 18.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A light source arranged to illuminate a non-patterning surface of a patterning device in a lithographic apparatus, wherein the light source is configured such that, in response to illumination from the light source, the non-patterning surface emits electrons due to the photoelectric effect.

2. The light source according to claim 1, wherein the light source is arranged to emit light with a wavelength that is greater than 91 nm.

3. The light source according to claim 1, wherein the power of the light emitted by the light source is less than 1 mW.

4. The light source according to claim 1, wherein the power of the light emitted by the light source is greater than 5 μW.

5. The light source according to claim 1, wherein the light source is tuneable so that the wavelength and/or power of the emitted light may be changed.

6. The light source according to claim 1, wherein the non-patterning surface of the patterning device is on the opposite side of the patterning device to a patterning surface of the patterning device.

7. The light source according to claim 1, wherein the lithographic apparatus is an EUV lithographic apparatus or a DUV lithographic apparatus.

8. A patterning device discharge system for use in a lithographic apparatus, the system comprising:
a patterning device;
a support structure configured to the patterning device in the lithographic apparatus; and
one or more light sources according to claim 1.

9. The system according to claim 8, wherein the support structure is arranged such that a non-patterning surface of the patterning device faces the support structure when the patterning device is held by the support structure; and
at least one light source is arranged to illuminate the non-patterning surface of the patterning device when the patterning device is held by the support structure.

10. The system according to claim 9, wherein the support structure comprises one or more openings; and
the at least one light source that is arranged to illuminate the non-patterning surface of the patterning device, when the patterning device is held by the support structure, is arranged to shine light through the one or more openings.

11. The system according to claim 9, wherein the at least one light source that is arranged to illuminate the non-patterning surface of the patterning device, when the patterning device is held by the support structure, is arranged in the support structure.

12. The system according to claim 8, further comprising a handler of the patterning device;
wherein the handler is arranged to move the patterning device away from the support structure to an illumination location; and
at least one light source is arranged to illuminate the patterning device when the patterning device is at the illumination location.

13. The system according to claim 8, wherein the lithographic apparatus is an EUV lithographic apparatus or a DUV lithographic apparatus.

14. A lithographic apparatus comprising:
a support structure configured to support a patterning device;
one or more light sources arranged to illuminate a non-patterning surface of the patterning device in the lithographic apparatus, wherein the one or more light sources are configured such that, in response to illumination from the one or more light sources, the non-patterning surface emits electrons due to the photoelectric effect; and
a controller arranged to control the illumination of the patterning device of the system by the one or more light sources.

15. The lithographic apparatus according to claim 14, wherein, when the patterning device of the system is charged, the controller is arranged to control the illumination of the patterning device by the one or more light sources of the system so that the patterning device is substantially discharged.

16. The lithographic apparatus according to claim 14, wherein the lithographic apparatus is an EUV lithographic apparatus or a DUV lithographic apparatus.

17. A method of reducing the charge of a charged non-patterning surface of a patterning device in a lithographic apparatus, the method comprising illuminating the non-patterning surface with light such that the non-patterning surface emits electrons due to the photoelectric effect.

18. The method according to claim 17, wherein the non-patterning surface of the patterning device is on the opposite side of the patterning device to a patterning surface of the patterning device.

19. A method comprising:
manufacturing a device using a patterning device; and
performing the method of claim 17.

20. The method of claim 17, wherein the lithographic apparatus is an EUV lithographic apparatus or a DUV lithographic apparatus.
